(19) United States
(12) Patent Application Publication
(10) Pub. No.: US 2005/0101135 A1
(43) Pub. Date: May 12, 2005

(54) Minimizing the loss of barrier materials during photoresist stripping

(75) Inventors: Rao Annapragada, Union City, CA (US); Helen Zhu, Fremont, CA (US)

Correspondence Address: Michael A. Kerr;Virtual Legal, Suite 211, 777 E. William St., Carson City, NV, 89701, US

(73) Assignee: Lam Research Corporation, Fremont, CA (US)

(21) Appl. No.: 10/712,326

(22) Filed: Nov. 12, 2003

(51) Int. Cl. H01L 21/302; H01L 21/461

(52) U.S. Cl. 438/689; 438/706; 438/725

(57) ABSTRACT

A method of removing a photoresist layer from an integrated circuit (IC) structure having an etched dielectric material with an exposed barrier layer that covers a copper interconnect. The barrier layer is composed of a material such as silicon nitride or silicon carbide. The method includes feeding a gas mixture that compromises carbon monoxide (CO) into a reactor. A plasma is then generated within the reactor. The photoresist layer is then selectively removed with little or no etching of the exposed barrier layer.

### BACKGROUND

1. Field of Invention

The present invention relates to the minimizing of the loss of a barrier layer during the stripping of an organic photoresist. More particularly, the invention relates to the etching of an integrated circuit (IC) structure having a barrier material such as silicon nitride or silicon carbide.

2. Description of Related Art

Semiconductor devices are typically formed on a semiconductor substrate and often include multiple levels of patterned and interconnected layers. For example, many semiconductor devices have multiple layers of conductive lines (e.g., interconnects). Conductive lines or other conducting structures, such as gate electrodes, are typically separated by dielectric material (i.e., insulating material) and may be coupled together, as needed, by vias through the dielectric material.

During the semiconductor integrated circuit (IC) fabrication process, devices such as component transistors are formed on a semiconductor wafer substrate. Various materials are then deposited on different layers in order to build a desired IC. Typically, conductive layers may include patterned metallization lines, polysilicon transistor gates and the like which are insulated from one another with dielectric materials such as low-k dielectric materials.

In integrated circuit manufacturing, the combination of copper interconnects and a dual damascene structure are being used to reduce the RC delays associated with signal propagation that was present in the prior art aluminum based IC structures. In dual damascene processing, instead of etching the conductor material, vias and trenches are etched into the dielectric material and filled with copper. The excess copper is removed by CMP leaving copper lines connected by vias for signal transmission. To reduce the RC delays even further, low dielectric constant materials are being used. The dielectric constant materials include silicon dioxide and low-k dielectric constant materials such as organosilicate glass (OSG) materials.

Low-k materials are incorporated into IC fabrication using a copper dual damascene process. A dual damascene structure employs an etching process that creates trenches for lines and holes for vias. The vias and trenches are then metallized to form the interconnect wiring. The two well-known dual damascene schemes are referred to as a via first sequence and a trench first sequence.

During the dual damascene process, one or more barrier layers are typically used to protect material adjacent the copper interconnects in the semiconductor devices from being poisoned by copper atoms diffusing from the copper interconnect into the adjacent material. For example, the barrier layer(s) may protect adjacent silicon-containing structures from being poisoned by copper atoms diffusing from the copper interconnect into the adjacent silicon-containing structures.

A typical barrier layer is also referred to as a “diffusion barrier layer” or as an “etch stop layer”. One commonly used barrier layer is silicon nitride (Si₃N₄) or SiN for short. Another commonly used barrier layer is silicon carbide which is also referred to as amorphous silicon carbide or some combination of SiC_{X}N_{Y}H_{Z}O_{W}.

During the etching of silicon and oxygen containing dielectrics, a flourine containing gas mixture is typically used to etch the silicon and oxygen containing dielectric. The fluorine containing gas mixtures reacts with the IC structure and produces a fluorinated polymer (CₓH_{y}F_{z}) that is deposited on the IC and in the reactor.

Typically, the process step that follows the etching of the dielectric is the removal or “stripping” of the photoresist layer. During the removal of the photoresist layer, an oxidizing gas mixture is used to remove the organic photoresist. In the prior art, the oxidizing gas mixture reacts with the fluorinated polymer to produce a gas mixture that etches the barrier layer. If the etching of the barrier layer results in opening the barrier layer, the IC structure is compromised from copper diffusion into the dielectric layer. Copper diffusion into the dielectric layer poisons the IC structure and compromises the dielectric properties of the IC.

### SUMMARY

A method of removing a photoresist layer from an integrated circuit (IC) structure that minimizes the loss of barrier materials from a barrier layer. The IC structure comprises a photoresist layer, an etched dielectric layer and an exposed barrier layer that covers a copper interconnect. In one embodiment, the etched dielectric layer is comprised of materials that include silicon and oxygen. In another embodiment the etched dielectric material is composed of materials such as silicon dioxide, silicon oxide, organosilicate glass, or fluorinated silicate glass. The exposed barrier layer is composed of a material such as silicon nitride or silicon carbide.

The method includes feeding a first gas mixture that includes inter alia carbon monoxide (CO) into a reactor. In one embodiment the first gas mixture comprises CO and oxygen (O₂). In another embodiment the first gas mixture comprises CO and nitrogen (N₂). Other gas mixtures include CO and gas mixtures selected from the group consisting of nitrogen (N₂)/oxygen (O₂), nitrous oxide (N₂O), ammonia (NH₃), nitrogen (N₂)/hydrogen (H₂), and water vapor (H₂O).

The method then proceeds to generate a plasma within the reactor. The photoresist layer is then selectively removed with little or no etching of the exposed barrier layer thereby minimizing the loss of silicon carbide or silicon nitride from the barrier layer. Although the exact mechanism is not known, it is hypothesized that the carbon monoxide (CO) scavenges fluorine released from the F containing polymer (CₓH_{y}F_{z}) deposited on the wafer and/or the reactor. By minimizing the loss of barrier layer, the integrity of the underlying copper interconnect is preserved.

### BRIEF DESCRIPTION OF THE DRAWINGS

Illustrative embodiments of the present invention are shown in the accompanying drawings wherein:

FIG. 1 is an illustrative system capable of removing a photoresist layer from an IC structure.

FIG. 2 is a flowchart for removing the photoresist layer and preserving the barrier layer.

FIG. 3A through FIG. 3F provides an isometric view of an illustrative IC structure in which the photoresist is removed used the methods described in FIG. 2.

### DETAILED DESCRIPTION

In the following detailed description, reference is made to the accompanying drawings, which form a part hereof, and which show illustrative embodiments. These embodiments are described in sufficient detail to enable those skilled in the art to practice the invention, and it is to be understood that other embodiments may be utilized and that structural, logical and process changes may be made without departing from the spirit and scope of the claims. The following detailed description is, therefore, not to be taken in a limited sense. The leading digit(s) of the reference numbers in the Figures corresponds to the figure number, with the exception of identical components that appear in multiple figures and are identified by the same reference numbers.

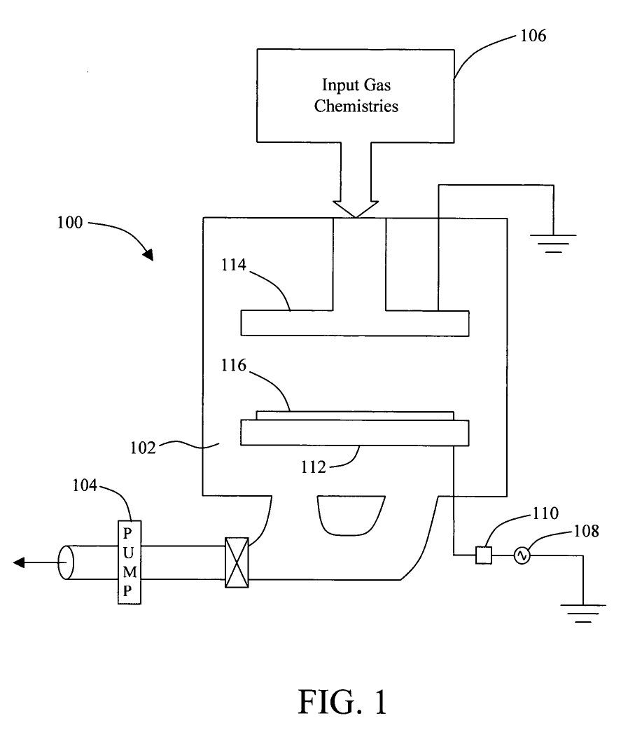

Referring to FIG. 1 there is shown an illustrative system capable of etching a silicon nitride or silicon carbide barrier layer from an IC structure. The illustrative system is also configured to perform barrier layer etching, dielectric etching and photoresist removal. The illustrative system is a parallel plate plasma system 100 such as 200 mm EXELAN HPT system available from Lam Research Corporation from Fremont, Calif. The system 100 includes a chamber having an interior 102 maintained at a desired vacuum pressure by a vacuum pump 104 connected to an outlet in a wall of the reactor. Etching gas can be supplied to the plasma reactor supplying gas from gas supply 106. A medium density plasma can be generated in the reactor by a dual frequency arrangement wherein RF energy from RF source 108 is supplied through a matching network 110 to a powered electrode 112. The RF source 108 is configured to supply RF power at 27 MHz and 2 MHz. Electrode 114 is a grounded electrode. A substrate 116 is supported by the powered electrode 112 and is etched and/or stripped with plasma generated by energizing the gasses into a plasma state. Other capacitively coupled reactors can also be used such as reactors where RF power is supplied to both electrodes such as the dual frequency plasma etch reactor described in commonly owned U.S. Pat. No. 6,090,304, the disclosure of which is hereby incorporated by reference.

Alternatively, the plasma can be produced in various other types of plasma reactors referred to as inductively coupled plasma reactor, an electron-cyclotron resonance (ECR) plasma reactor, a helicon plasma reactor, or the like. Such plasma reactors typically have energy sources which use RF energy, microwave energy, magnetic fields, etc. to produce a medium to high density plasma. For instance, a high density plasma could be produced in a Transformer Coupled Plasma etch reactor available from Lam Research Corporation which is also called an inductively coupled plasma reactor.

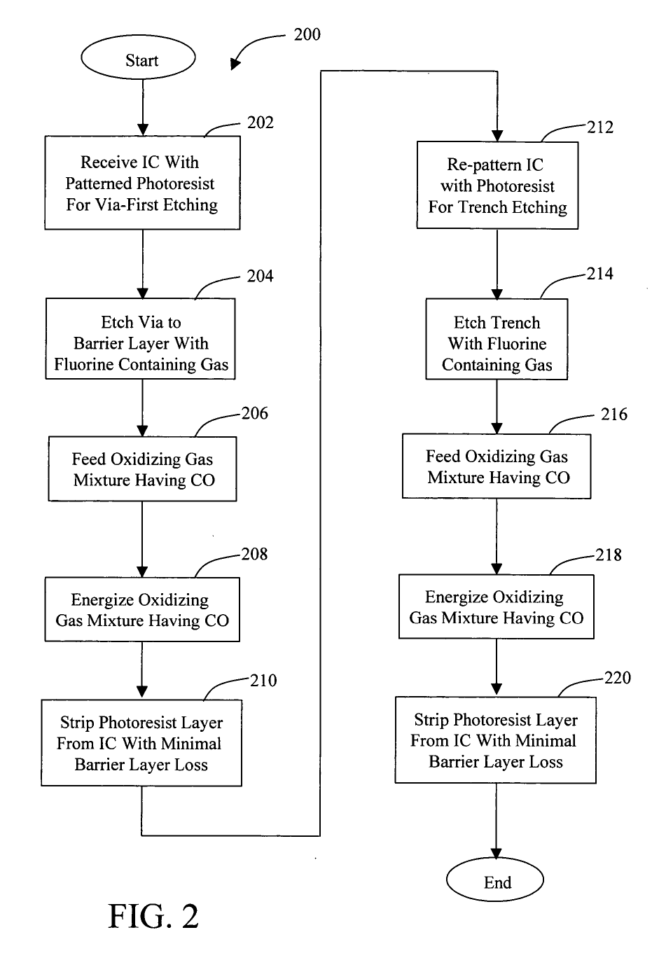

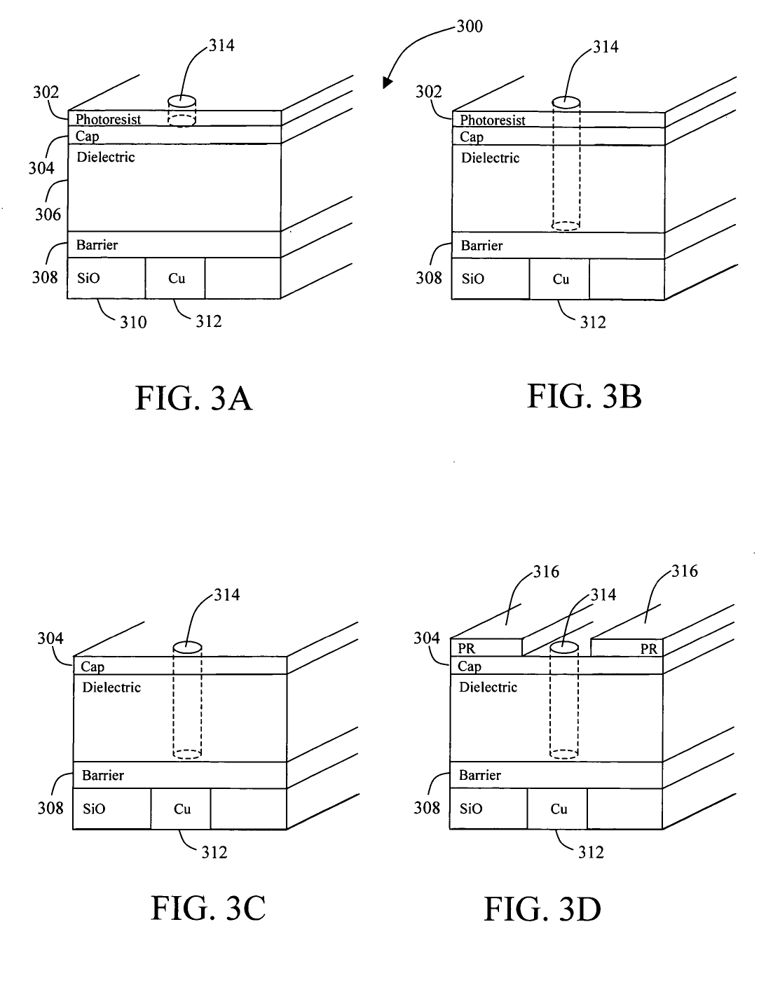

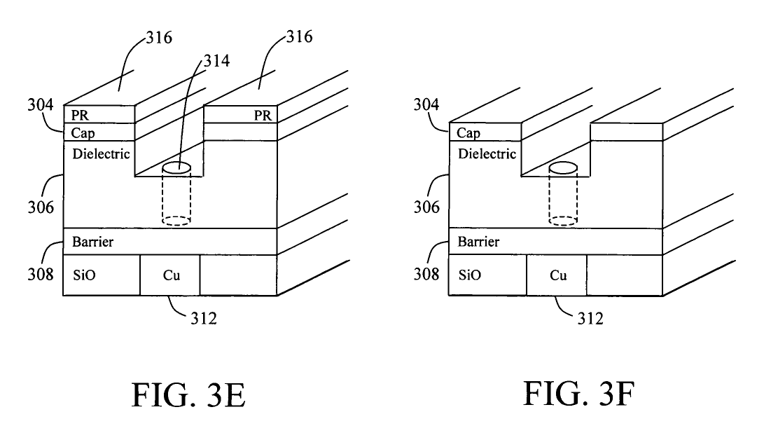

Referring to FIG. 2 there is shown a flowchart of a method for removing or “stripping” a photoresist layer from an IC structure. The method described in FIG. 2 minimizes the loss of barrier materials from a barrier layer. The method is applied to an illustrative IC structure 300 shown in FIG. 3A that has been etched as depicted by FIG. 3B. As described in block 202 of FIG. 2, the illustrative IC in FIG. 3A is received in a reactor for etching.

Referring back to FIG. 3A there is shown the illustrative IC structure that includes a first photoresist layer 302, a second cap layer 304, a third dielectric layer 306, a fourth barrier layer 308, and a fifth layer 310 having a copper interconnect 312. The illustrative IC structure has a patterned first photoresist layer 302.

During the etching process described in block 204 of FIG. 2, the second cap layer 304 and the third dielectric layer 306 are etched and the fourth barrier layer 308 is exposed. The exposed fourth barrier layer 308 covers the fifth layer 310 which has the copper interconnect 312.

By way of example and not of limitation, the first photoresist layer 302 for the illustrative IC structure 300 is an organic photoresist. For the illustrative example, the organic photoresist is a 193 nm photoresist or a 248 nm photoresist from the Shipley Company.

The illustrative second cap layer 304 is composed of such cap materials as Silicon Dioxide (SiO₂), Silicon Oxynitride (SiON), silicon carbide and silicon nitride. The cap layer 304 provides protection for the underlying third dielectric layer during the etching and stripping process. The third dielectric layer 306 is composed of such materials as silicon dioxide, silicon oxide, organosilicate glass, or fluorinated silicate glass. The selection of the cap layer material 304 depends on the dielectric properties of the underlying third dielectric layer. For example with a silicon dioxide dielectric layer, the cap layer 304 may be composed silicon oxynitride, silicon carbide or silicon nitride. For organosilicate glass or fluorinated silicate glass, the cap layer 304 may be composed of silicon dioxide, composed silicon oxynitride, silicon carbide or silicon nitride.

In an alternative embodiment there is no second cap layer 304 or the second cap layer 304 has been removed prior to the removal of the first photoresist layer. The cap layer may be removed during dual damascene processing. Thus, the method for removing the photoresist layer that is described herein may be applied to an IC structure that either includes a second cap layer 304 or does not include a second cap layer 304.

The IC structure also includes the illustrative third dielectric layer 306. The third dielectric layer 306 may be composed of such materials as silicon dioxide (SiO₂), silicon oxide (SiO), organosilicate glass (OSG), or fluorinated silicate glass (FSG). The silicon dioxide may be deposited from the precursor TEOS or silane using CVD tools made by Applied Materials of Santa Clara, Calif. For the illustrative IC structure the illustrative dielectric is represented as SiO₂ in FIG. 3 and FIG. 4. In another embodiment, the dielectric layer is an OSG material such as CORAL™ from Novellus Systems of San Jose, Calif., or BLACK DIAMOND™ from Applied Materials of Santa Clara, Calif., or any other such OSG materials. In yet another embodiment, the dielectric material is a fluorinated silicate glass (FSG) film deposited using CVD tools from Novellus Systems of San Jose, Calif. Additionally, it shall be appreciated by those skilled in the art that the dielectric material may also be a porous dielectric material having an illustrative void space of greater than 30%.

The illustrative fourth barrier layer 308 is composed of barrier materials. An illustrative barrier material includes silicon nitride (Si₃N₄) or SiN for short. Another illustrative barrier material is silicon carbide which is also referred to as amorphous silicon carbide or some combination of SiC_{X}N_{Y}H_{Z}O_{W}. A typical barrier layer 308 is also referred to as a “diffusion barrier layer” or as an “etch stop layer”. It shall be appreciated by those skilled in the art that the barrier layer provides protection from copper diffusion.

The illustrative fifth layer includes an interconnect 312 that conducts electricity. The conductive interconnect abuts the fourth dielectric layer 308. Typically, the fifth layer also includes another dielectric material 310 that is adjacent or “surrounding” the conductive interconnect 312. For the illustrative example, the interconnect 312 is composed of copper. Alternatively, the interconnect may be composed of other conductors such as tungsten or aluminum. In the illustrative IC structure, the interconnect is surrounded by a dielectric material such as silicon oxide 310 (SiO).

Referring to FIG. 2 and FIG. 3, at block 202 the illustrative IC structure 300 with the patterned photoresist is received in the illustrative reactor 100 of FIG. 1. The photoresist layer 302 is patterned for via-first etching. The method then proceeds to block 204.

At block 204, the illustrative cap layer 304 and the illustrative dielectric layer 306 are etched using a fluorine containing gas mixture. The type of fluorine containing gas mixture that is applied is dependent on the type of cap layer 304 and dielectric layer 306. By way of example and not of limitation, a fluorine containing gas mixture may include a fluorine (F₂) gas, a nitrogen trifluoride (NF₃) gas, a fluorocarbon gas, or any combination thereof. Typically, the fluorocarbon gas has a chemical composition of CₓF_{y}, or CₓF_{y}H_{z}, wherein x,y and z represent integers. Further still, the etchant gas mixture may include an inert gas as a diluent. By way of example and not of limitation, the inert gases includes the nobles gases Ar, He, Ne, Kr, and Xe.

It is well known that after etching using a fluorine containing gas, a fluorinated polymer (CₓH_{y}F_{z}) is generated which is deposited on the IC structure and in the reactor. As previously mentioned, the fluorinated polymer then reacts with well-known gas mixtures that are used to strip the photoresist.

At block 206, a first gas mixture that contains carbon monoxide (CO) is fed into the reactor 100. The first gas mixture also includes one or more gases or gas mixtures. In one embodiment the oxidizing gas mixture comprises oxygen (O₂) and carbon monoxide. In another embodiment, the gas mixture comprises nitrogen (N₂) and carbon monoxide. Another carbon monoxide gas mixture comprises the gas combination of nitrogen (N₂) and oxygen (O₂). Yet another gas mixture that would include carbon monoxide also comprises the gas nitrous oxide (N₂O). Yet still another gas mixture that would include carbon dioxide comprises the gas ammonia (NH₃). Further still another gas mixture that would include carbon monoxide comprises the gas combination of nitrogen (N₂) and hydrogen (H₂). Still another gas mixture that includes carbon monoxide also comprises water vapor (H₂O).

The method then proceeds to block 208 where a plasma is generated within the reactor by energizing the oxidizing gas mixture having carbon monoxide. At block 210, the photoresist layer is selectively removed with little or no etching of the exposed barrier layer thereby minimizing the loss of silicon carbide or silicon nitride from the barrier layer. Although the exact mechanism is not known, it is hypothesized that the carbon monoxide (CO) scavenges fluorine from polymerized fluorine (CₓH_{y}F_{z}) deposited on the IC and/or the reactor. By minimizing the loss of barrier layer, the integrity of the underlying copper interconnect is preserved. Additionally, the use of carbon monoxide in the stripping process enables thinner barrier layers to be applied to the IC structure, and thereby results in reduced capacitance of the copper interconnect. Furthermore, the use of carbon monoxide in the stripping process enables the stripping process to be performed in the same reactor 100 that is used for etching.

For an illustrative embodiment the first gas mixture described above is composed of carbon monoxide (CO), nitrogen (N₂) and oxygen (O₂). In a rather broad illustrative embodiment, the range for the processing parameters may be practiced at operating pressures of 5 to 2000 mTorr, at power ranges of 50 to 1000 W for RF power, at N₂ flow rates of 10 to 5000 sccm, at O₂ flow rates of 10 to 5000 sccm, and CO flow rates of 10 to 5000 sccm.

In a less broad illustrative embodiment having a RF source configured to supply RF power at 27 MHz and 2 MHz, the range for the processing parameters may be practiced at operating pressures of 20 to 1000 mTorr, at 0 to 600 W for 27 MHz RF power, at 0 to 6000 W for 2 MHz RF power, at N₂ flow rates of 50 to 2000 sccm, at O₂ flow rates of 50 to 2000 sccm, and CO flow rates of 50 to 2000 sccm.

In an even less broad illustrative embodiment that that uses the illustrative system 100, the range for the processing parameters may be practiced at operating pressures of 30 to 900 mTorr, at 0 to 400 W for 27 MHz RF power, at 0 to 400 W for 2 MHz RF power, at N₂ flow rates of 100 to 1000 sccm, at O₂ flow rates of 100 to 1000 sccm, and CO flow rates of 100 to 1000 sccm.

By way of example and not of limitation, a plurality of operating process parameters for removing the organic photoresist from an IC structure having a silicon dioxide (SiO₂) dielectric layer that has been etched with a fluorine containing gas, and a silicon nitride barrier layer are shown in Table 1.

TABLE 1
Illustrative Process Parameter For Stripping Photoresist

| | | 27 MHz | 2 MHz | N₂ | O₂ | CO | SiN | PR |
|---|---|---|---|---|---|---|---|---|
| Run | Press | RF Power | RF Power | Flow | Flow | Flow | ER | ER |
| # | (mTorr) | (W) | (W) | (sccm) | (sccm) | (sccm) | (Å/min) | (Å/min) |
| 1 | 400 | 300 | 300 | 200 | 1000 | 400 | 10 | 10000 |
| 2 | 400 | 300 | 0 | 0 | 1000 | 400 | 5 | 5000 |

In Table 1, the process parameters for two different “runs” are shown. The runs were performed on a 200 mm wafer at 20° C. The temperature range may vary from 0° C. to 50° C. The etch time during the stripping of the organic photoresist, referred to as “PR” in Table 1, was 60 seconds. The stripping period may vary from 10 to 120 seconds. The selectivity for the first run is based on taking the ratio of the photoresist (PR) stripping rate to the SiN etch rate which results in a selectivity ratio of 1000. For the second run the selectivity ratio between the photoresist to the SiN barrier layer is 1000.

At process block 212, the illustrative IC structure is re-patterned for trench etching. It shall be appreciated by those skilled in the art that this process typically requires removing the wafer associated with the illustrative IC structure from the reactor 100. The wafer is re-patterned using well known lithography systems and methods. The process of re-patterning includes generating a patterned photoresist layer 316 as shown in FIG. 3D.

At process block 214, the wafer is returned to the illustrative reactor 100. The IC structure corresponding to the wafer is then prepared for trench etching using a fluorine containing gas as described above in block 204. After completion of the trench etching the method proceeds to block 216 where the IC structure is prepared for photoresist removal in the same illustrative reactor 100. As described in block 206, a second gas mixture that comprises carbon monoxide is fed into reactor 100 at block 216. At block 218, the second gas mixture that comprises carbon monoxide is then energized in a fashion similar to description provided above in block 208. It shall be appreciated by those skilled in the art having the benefit of this disclosure that the first gas mixture and second gas mixture may have similar and/or different chemical properties. At block 218, the photoresist is then stripped with little or no loss of barrier materials, thereby resulting in minimizing the loss of barrier layer materials during the photoresist stripping process.

Referring to FIG. 3A through FIG. 3F there is shown a plurality of isometric views 300 regarding the etching of a barrier layer in which the barrier layer is composed of silicon nitride and/or silicon carbide as described above. The isometric views of the illustrative IC structure 300 provide a visual representation of the method described above.

FIG. 3A shows an isometric view of the illustrative IC structure 300 having a first patterned photoresist layer 302, a second cap layer 304 composed of SiO₂, a third dielectric layer 306, a fourth layer 308, and a fifth layer that includes the copper interconnect 312. The IC structure 300 has been described in further detail above.

In FIG. 3B, via 314 has been etched through the second cap layer 304 and the third dielectric layer 306 to the exposed fourth barrier layer 308. Via 314 has been etched using a fluorine containing gas mixture as described at block 204. As previously described, the etching process results in generating the polymerized fluorine that is deposited on the wafer and reactor.

Referring to FIG. 3C, the photoresist layer 304 has been removed from the IC structure 300. The photoresist is removed or stripped using the methods described above in blocks 206, 208, and 210. In summary, the photoresist layer is removed with plasma generated from the first gas mixture that comprises carbon monoxide. The inventor's hypothesize that during the stripping process the first gas mixture converts the polymerized fluorine to a fluorine containing gas, and the carbon monoxide reacts with or “scavenges” the fluorine from the fluorine containing gas, so that the fluorine containing gas etch little or none of the exposed barrier layer 308.

In FIG. 3D, the illustrative IC structure 300 is re-patterned for trench etching as described above in process block 212. The re-patterning process includes generating a trench patterned photoresist layer 316. The wafer is then returned to the illustrative reactor 100 and the IC structure is prepared for trench etching as described above in block 214.

Referring now to FIG. 3F, the IC structure is shown after the trench etching is completed and the second cap layer 304 and the third dielectric layer 306 is etched. As described above, a fluorine containing gas is again used to conduct the trench etching. After completion of the trench etching the IC structure is prepared for photoresist stripping.

In FIG. 3E, the IC structure is shown after the photoresist layer 316 has been removed using the second gas mixture described in blocks 216 and 218 that comprises carbon monoxide. During the stripping process, there is little or no loss of barrier materials. This stripping process results in minimizing the loss of the barrier layer 308 materials.

Although the description about contains many limitations in the specification, these should not be construed as limiting the scope of the claims but as merely providing illustrations of some of the presently preferred embodiments of this invention. Many other embodiments will be apparent to those of skill in the art upon reviewing the description. Thus, the scope of the invention should be determined by the appended claims, along with the full scope of equivalents to which such claims are entitled.

1. A method of removing a photoresist layer from an integrated circuit (IC) structure having an etched dielectric layer with an exposed barrier layer, wherein said dielectric layer comprises silicon and oxygen and said barrier layer is composed of a material selected from a group consisting of silicon nitride and silicon carbide, said method comprising:
firstly, etching said dielectric layer and exposing said barrier layer;
secondly, feeding a first gas mixture into a reactor wherein said first gas mixture comprises carbon monoxide (CO);
generating a plasma in said reactor; and
selectively removing said photoresist layer with little or no etching of said exposed barrier layer, thereby minimizing the loss of said exposed barrier material during said removing of said photoresist layer.

2. The method of claim 1 wherein said dielectric material is silicon dioxide.

3. The method of claim 1 wherein said first gas mixture further comprises oxygen (O₂).

4. The method of claim 1 wherein said first gas mixture further comprises nitrogen (N₂).

5. The method of claim 1 wherein said first gas mixture further comprises the gas mixtures selected from the group consisting of oxygen (O₂), nitrogen (N₂), nitrogen (N₂)/oxygen (O₂), nitrous oxide (N₂O), ammonia (NH₃), nitrogen (N₂)/hydrogen (H₂), and water vapor (H₂O).

6. The method of claim 1 wherein said etched dielectric material is composed of a material selected from the group consisting of silicon dioxide, silicon oxide, organosilicate glass, and fluorinated silicate glass.

7. The method of claim 1 wherein said IC structure further comprises a cap layer located between said dielectric and said photoresist, said cap layer is composed of a material selected from the group consisting of silicon dioxide, silicon oxynitride, silicon carbide and silicon nitride.

8. The method of claim 1 wherein said reactor used to remove said photoresist from said IC structure is also used to etch said dielectric.

9. A method of removing a photoresist layer from an integrated circuit (IC) structure having an etched first dielectric layer, an exposed second barrier layer wherein said barrier layer is composed of a material selected from a group consisting of silicon nitride and silicon carbide, and a third layer that includes a conductive interconnect that abuts said barrier layer and a second dielectric material adjacent to said conductive interconnect, said barrier layer between said etched first dielectric layer and said third layer, comprising:
firstly, etching said dielectric layer and exposing said barrier layer;
secondly, feeding a first gas mixture into a reactor wherein said first gas mixture comprises carbon monoxide (CO);
generating a plasma in said reactor; and
selectively removing said photoresist layer with little or no etching of said exposed barrier layer, thereby minimizing the loss of said exposed barrier material during said removing of said photoresist layer.

10. The method of claim 9 wherein said first dielectric layer and said second dielectric layer is comprised of materials that include silicon and oxygen.

11. The method of claim 9 wherein said first gas mixture comprises the gas mixtures selected from the group consisting of oxygen (O₂), nitrogen (N₂), nitrogen (N₂)/oxygen (O₂) nitrous oxide (N₂O), ammonia (NH₃), nitrogen (N₂)/hydrogen (H₂), and water vapor (H₂O).

12. The method of claim 9 wherein said etched first dielectric layer is composed of a material selected from the group consisting of silicon dioxide, silicon oxide, organosilicate glass, and fluorinated silicate glass.

13. The method of claim 9 wherein said IC structure further comprises a cap layer located between said photoresist layer and said first dielectric layer, said cap layer is composed of a material selected from the group consisting of silicon dioxide, silicon oxynitride, silicon carbide and silicon nitride.

14. The method of claim 9 wherein said reactor used to remove said photoresist from said IC structure is also used to etch said first dielectric layer.

15. A method of removing a photoresist layer from an integrated circuit (IC) structure having an etched dielectric layer with an exposed barrier layer, wherein said barrier layer is composed of a material selected from a group consisting of silicon nitride and silicon carbide, said method comprising:
firstly, etching said dielectric layer and exposing said barrier layer;
secondly, feeding a first gas mixture into a reactor wherein said oxidizing gas mixture comprises carbon monoxide (CO), wherein said oxidizing gas mixture comprises the gas mixtures selected from the group consisting of oxygen (O₂), nitrogen (N₂), nitrogen (N₂)/oxygen (O₂), nitrous oxide (N₂O), ammonia (NH₃), nitrogen (N₂)/hydrogen (H₂), and water vapor (H₂O);
generating a plasma in said reactor; and
selectively removing said photoresist layer with little or no etching of said exposed barrier layer, thereby minimizing the loss of said exposed barrier material during said removing of said photoresist layer.

16. The method of claim 13 wherein said dielectric layer is comprised of materials that include silicon and oxygen.

17. The method of claim 13 wherein said etched dielectric layer is composed of a material selected from the group consisting of silicon dioxide, silicon oxide, organosilicate glass, and fluorinated silicate glass.

18. The method of claim 13 wherein said IC structure further comprises a cap layer located between said dielectric layer and said photoresist, said cap layer is composed of a material selected from the group consisting of silicon dioxide, silicon oxynitride, silicon carbide and silicon nitride.

19. The method of claim 13 wherein said reactor used to remove said photoresist from said IC structure is also used to etch said dielectric layer.
